(19) United States
(12) Patent Application Publication
(10) Pub. No.: US 2015/0069470 A1
(43) Pub. Date: Mar. 12, 2015

(54) INTEGRATED CIRCUIT DEVICE

(71) Applicant: KABUSHIKI KAISHA TOSHIBA, Tokyo (JP)

(72) Inventor: Atsushi KANEKO, Kanagawa (JP)

(73) Assignee: KABUSHIKI KAISHA TOSHIBA, Tokyo (JP)

(21) Appl. No.: 14/194,633

(22) Filed: Feb. 28, 2014

(30) Foreign Application Priority Data
Sep. 6, 2013 (JP) 2013-185602

(51) Int. Cl. H01L 27/118; H01L 27/092

(52) U.S. Cl. CPC H01L 27/11807; H01L 27/092
USPC 257/206; 438/128

(57) ABSTRACT

An integrated circuit device includes a plurality of basic cells that each have a first transistor pair including two p-channel transistors of a first-type and a second transistor pair including two p-channel transistors of a second-type. The second-type transistors are configured to consume less power and operate more slowly than the first-type transistors. The basic cell further includes a third transistor pair of two n-channel transistors of a third-type. The third transistor pair is disposed between the first and second transistor pairs. Gate electrodes are separately provided for each transistor in the first, second, and third transistor pairs. The basic cell thus formed can be used to fabricate various circuit elements by making wiring connections between various transistor pairs and/or basic cells.

### CROSS-REFERENCE TO RELATED APPLICATION

This application is based upon and claims the benefit of priority from Japanese Patent Application No. 2013-185602, filed Sep. 6, 2013, the entire contents of which are incorporated herein by reference.

### FIELD

Embodiments described herein relate generally to integrated circuit devices.

### BACKGROUND

A gate array method is one of the methods for producing an application-specific integrated circuit (ASIC). The gate array method is a method by which a common process is used to form an array of transistors or common circuit elements. The transistor gates can then be connected (wired) to each other by formation of a wiring layer in accordance with a specific integrated circuit needed by the user for an application.

In the gate array method, to make the high-speed operation characteristics and the low-power consumption characteristics of the integrated circuit compatible with each other, it is possible to form a “master slice” arrangement in which a column including vertically arranged basic cells, each including a high-speed operation transistor, and a column including vertically arranged basic cells, each including a low-power consumption transistor, are alternately disposed. Since the two types of transistors may be used, compatibility between the high-speed operation characteristics and the low-power consumption characteristics can be provided. However, since it is rare that a nearly equal number of the two types of transistors is used in the integrated circuit, many transistors that are not used as circuit elements remain on the master slice. These unused transistors cause an increase in the area of the integrated circuit and an increase in a production cost.

### DESCRIPTION OF THE DRAWINGS

FIG. 1 is a plan view of a basic cell of a first embodiment.

FIG. 2 is a diagram of part of the surface of a master slice of the first embodiment.

FIGS. 3A and 3B are examples of an integrated circuit using the basic cell of the first embodiment.

FIGS. 4A and 4B are examples of the integrated circuit using the basic cell of the first embodiment.

FIGS. 5A and 5B are examples of the integrated circuit using the basic cell of the first embodiment.

FIG. 6 is an example of the integrated circuit using the basic cell of the first embodiment.

FIG. 7 is a plan view of a basic cell of a second embodiment.

### DETAILED DESCRIPTION

According to the present exemplary embodiments, there is provided an integrated circuit device that is capable of producing an integrated circuit in which the high-speed operation characteristics and the low-power consumption characteristics are compatible with each other while reducing the transistors that are not used as circuit elements.

In general, according to one embodiment, an integrated circuit device includes a plurality of basic cells each including a first transistor pair having two p-channel transistors of a first-type and a second transistor pair having two p-channel transistors of a second-type. The second-type transistors are configured to consume less power and operate more slowly than the first-type transistors. The basic cell further includes a third transistor pair having two n-channel transistors of a third-type. The third transistor pair is disposed between the first and second transistor pairs. Gate electrodes are separately provided for each transistor in the first, second, and third transistor pairs.

In some embodiments, each basic cell includes a first transistor pair including two p-type high-speed transistors, a second transistor pair including two p-type low-power transistors having a property of consuming a lower amount of power and operating more slowly than the p-type high-speed transistors, a third transistor pair that includes two n-type transistors and is disposed in such a way as to be sandwiched between the first transistor pair and the second transistor pair, and a plurality of gate electrodes provided for each transistor.

Hereinafter, embodiments will be described with reference to the drawings. However, the inventions are not limited to the embodiments described below. Incidentally, common portions in the drawings are identified with common reference symbols, and overlapping explanations may be omitted. Moreover, the drawings are schematic diagrams for explaining the embodiments and facilitating the understanding thereof and include some portions whose shapes, dimensions, ratios, etc. are different from the shapes, dimensions, ratios, etc. of an actual device, but design changes of the shapes, dimensions, ratios, etc. may be appropriately performed in consideration of the following explanations and publicly known techniques.

### First Embodiment

### Basic Cell

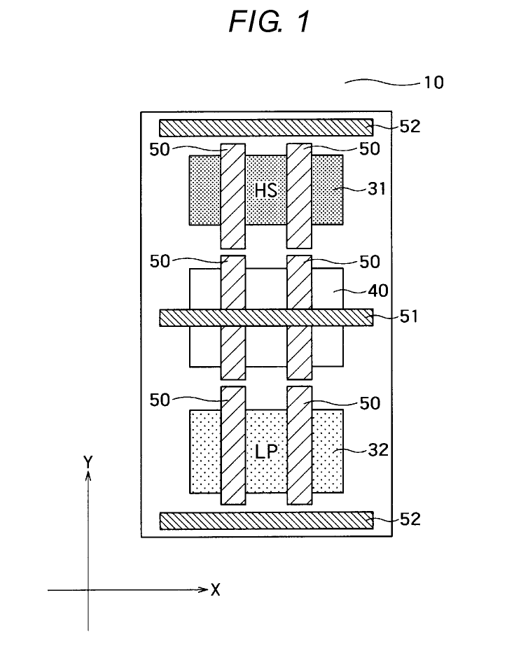

FIG. 1 depicts a basic cell 10 of a first embodiment.

The basic cell 10 includes a p-type high-speed transistor pair 31 including two p-channel high-speed operation transistors (hereinafter, p-type high-speed transistors: HS), a p-type low-power transistor pair 32 including two p-channel low-power consumption transistors (hereinafter, p-type low-power transistors: LP), and an n-type transistor pair 40 including two n-channel transistors (hereinafter, n-type transistors). The basic cell 10 includes three rows when viewed from above, as depicted in the FIG. 1. In a first row (the top row in FIG. 1), the p-type high-speed transistor pair 31 is disposed, and, in a third row (the bottom row in FIG. 1), the p-type low-power transistor pair 32 is disposed. Furthermore, in a second row (the center row in FIG. 1) sandwiched between the p-type high-speed transistor pair 31 and the p-type low-power transistor pair 32, the n-type transistor pair 40 is disposed.

A plurality of gate electrodes 50 are provided for each transistor. The gate electrodes 50 are not electrically connected to one another and are independent for each transistor when initially fabricated.

On the n-type transistor pair 40, a power-supply wiring electrode 51 extending in an X direction of the drawing is provided. Incidentally, in FIG. 1, although the power-supply wiring electrode 51 seems to intersect the gate electrodes 50 on the n-type transistor pair 40 as depicted in FIG. 1, the power-supply wiring electrode 51 and the gate electrodes 50 are electrically separated from each other. Moreover, two GND wiring electrodes 52 extending in the X direction are provided in such a way as to sandwich the three transistor pairs 31, 32, and 40. That is, a first GND wiring electrode 52 is located above (towards the top of page) the first row and a second GND wiring electrode 52 is below (towards the bottom of page) the third row, as depicted in FIG. 1.

The n-type transistor pair 40 is an n-type transistor pair that can be combined with both the p-type high-speed transistor and the p-type low-power transistor to provide an integrated circuit. For example, the n-type transistor pair 40 may be an n-type high-speed transistor pair or an n-type low-power transistor pair. Alternatively, the n-type transistor pair 40 may include two n-type intermediate level transistors having characteristics intermediate between the high-speed transistor and the low-power transistor.

### Master Slice

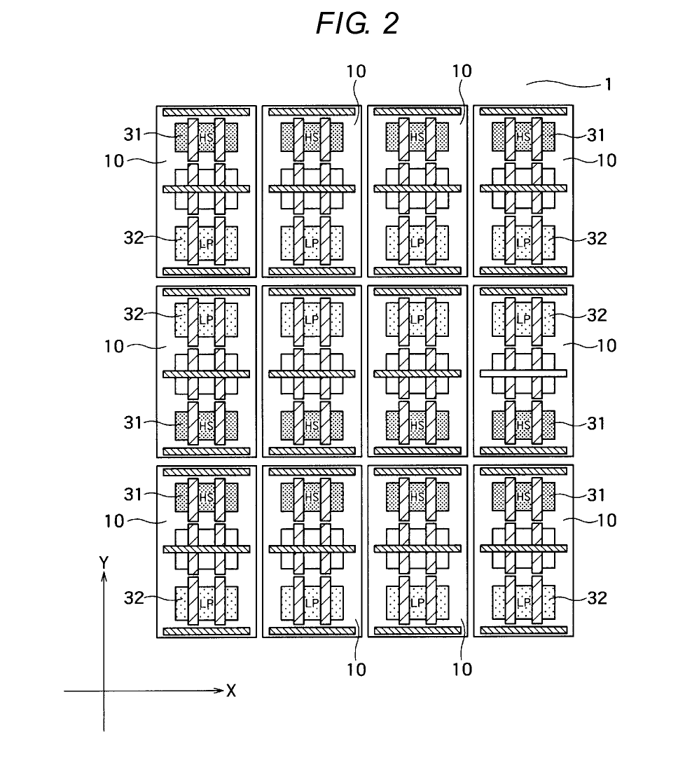

FIG. 2 depicts part of the surface of a master slice (an integrated circuit device adopting a master slice configuration) 1 according to a first embodiment.

On the surface of the master slice 1, a plurality of basic cells 10 are disposed in a matrix along the X direction and the Y direction. Specifically, some of the basic cells 10 are disposed in such a way that the basic cells 10 are turned upside down (depicted as the second row from above in FIG. 2). By arranging the basic cells 10 in this manner the p-type high-speed transistor pairs 31 are allowed to lie next to each other and the p-type low-power transistor pairs 32 are allowed to lie next to each other between adjacent basic cells 10. As a result of the transistor pairs 31 lying next to each other and the transistor pairs 32 lying next to each other, the active regions of the p-type transistors of the same type is more easily formed uniformly. Therefore, each p-type transistor is formed with a higher degree of accuracy.

### Method of Formation of a Transistor

Hereinafter, a method of formation of a transistor included in the basic cell 10 will be described. The p-type low-power transistor has the property of consuming a lower amount of power and operating more slowly than the p-type high-speed transistor. In addition, the two types of p-type transistors (the p-type high-speed transistor and the p-type low-power transistor) may be formed separately by adjusting the concentration of an impurity injected into a channel region of a transistor. For example, a transistor having a relatively high p-type impurity concentration in a channel region has a greater threshold value (Vth) and becomes a low-power transistor. On the other hand, a transistor having a relatively low p-type impurity concentration in a channel region has a smaller Vth and becomes a high-speed transistor.

The n-type transistor may also be formed in a similar manner. For example, to form an n-type low-power transistor, the n-type impurity concentration of a channel region is simply increased relatively to make the Vth of the transistor closer or equal to the Vth of the p-type low-power transistor. Therefore, the Vth of the n-type low-power transistor is closer to the Vth of the p-type low-power transistor as compared to the Vth of the p-type high-speed transistor. On the other hand, to form an n-type high-speed transistor, the n-type impurity concentration of a channel region is simply decreased relatively to make the Vth of the transistor closer or equal to the Vth of the p-type high-speed transistor. Therefore, the Vth of the n-type high-speed transistor is closer to the Vth of the p-type high-speed transistor as compared to the Vth of the p-type low-power transistor. Moreover, when an n-type intermediate level transistor is formed, the impurity concentration is adjusted so that the transistor has a Vth intermediate between the Vth of the p-type low-power transistor and the Vth of the p-type high-speed transistor. Incidentally, when the impurity concentrations of the channel regions of the n-type transistor and the p-type transistor are made to be equal to each other, the Vth of the n-type transistor becomes smaller than the Vth of the p-type transistor and the operation speed of the n-type transistor becomes higher than the operation speed of the p-type transistor.

### Integrated Circuit

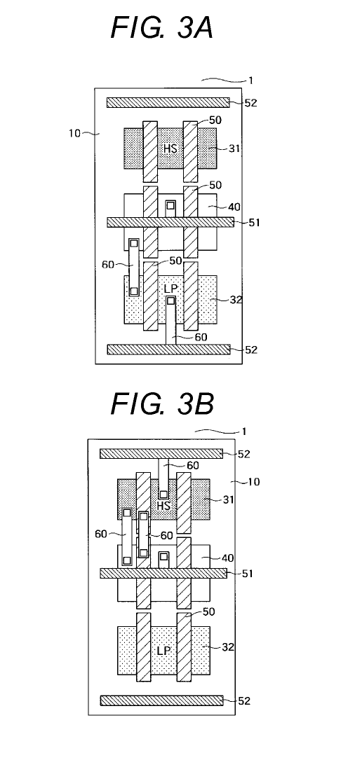

FIGS. 3A and 3B to FIG. 6 depict examples of an integrated circuit including the master slice 1.

The integrated circuits of FIGS. 3A and 3B are configured by forming wiring lines 60 on one basic cell 10 of the master slice 1. Specifically, FIG. 3A depicts an inverter (INV) circuit using the p-type low-power transistor pair 32 and the n-type transistor pair 40, and FIG. 3B depicts an INV circuit using the p-type high-speed transistor pair 31 and the n-type transistor pair 40. In these examples, the gate electrodes 50 of the p-type low-power transistor pair 32 or the p-type high-speed transistor pair 31 with the n-type transistor pair 40 are electrically connected to each other via the wiring lines 60. The drains of the p-type low-power transistor pair 32, the p-type high-speed transistor pair 31, and the n-type transistor pair 40 are connected via the wiring lines 60. Furthermore, the sources of the transistor pairs 31, 32, and 40 are connected to the power-supply wiring electrode 51 or the GND wiring electrode 52 via the wiring lines 60.

In the INV circuits of FIGS. 3A and 3B, unused transistor pairs that are not used as circuit elements are the p-type high-speed transistor pair 31 of FIG. 3A and the p-type low-power transistor pair 32 of FIG. 3B. That is, in these INV circuits, the number of unused transistor pairs that are not used as circuit elements is one in each of the two basic cells 10. Incidentally, the unused transistor may be used as a decoupling capacitor for ensuring the stability of a power supply.

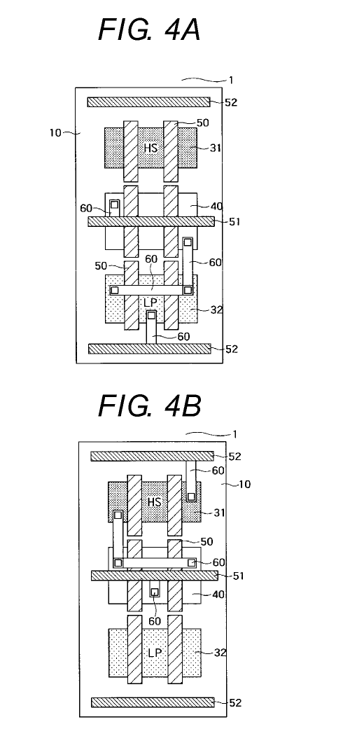

The integrated circuits of FIGS. 4A and 4B are also configured by forming the wiring lines 60 on one basic cell 10. Specifically, FIG. 4A depicts a NAND circuit using the p-type low-power transistor pair 32, the n-type transistor pair 40, and the wiring lines 60 electrically connecting the p-type low-power transistor pair 32 and the n-type transistor pair 40, and FIG. 4B depicts a NOR circuit using the p-type high-speed transistor pair 31, the n-type transistor pair 40, and the wiring lines 60 electrically connecting the p-type high-speed transistor pair 31 and the n-type transistor pair 40. The unused transistor pairs that are not used as circuit elements in these integrated circuits are the p-type high-speed transistor pair 31 of FIG. 4A and the p-type low-power transistor pair 32 of FIG. 4B. That is, in these integrated circuits, the number of unused transistor pairs is one in each of the two basic cells 10.

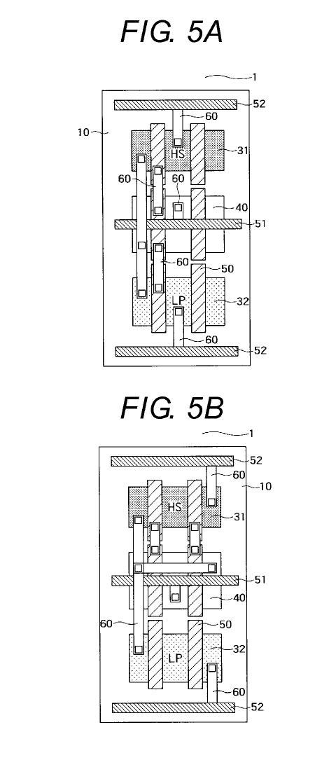

The integrated circuits of FIGS. 5A and 5B are also configured by forming the wiring lines 60 on one basic cell 10. Specifically, FIG. 5A depicts an INV circuit using the p-type high-speed transistor pair 31, the p-type low-power transistor pair 32, the n-type transistor pair 40, and the wiring lines 60 electrically connecting the p-type high-speed transistor pair 31, the p-type low-power transistor pair 32, and the n-type transistor pair 40, and FIG. 5B depicts a NOR circuit using the p-type high-speed transistor pair 31, the p-type low-power transistor pair 32, the n-type transistor pair 40, and the wiring lines 60 electrically connecting the p-type high-speed transistor pair 31, the p-type low-power transistor pair 32, and the n-type transistor pair 40. As depicted in FIGS. 5A and 5B, even in an integrated circuit including both of the two types of p-type transistor pairs 31 and 32, since one basic cell 10 has the two types of p-type transistor pairs 31 and 32, the integrated circuit may be configured without requiring the wiring lines 60 to be drawn out a long distance.

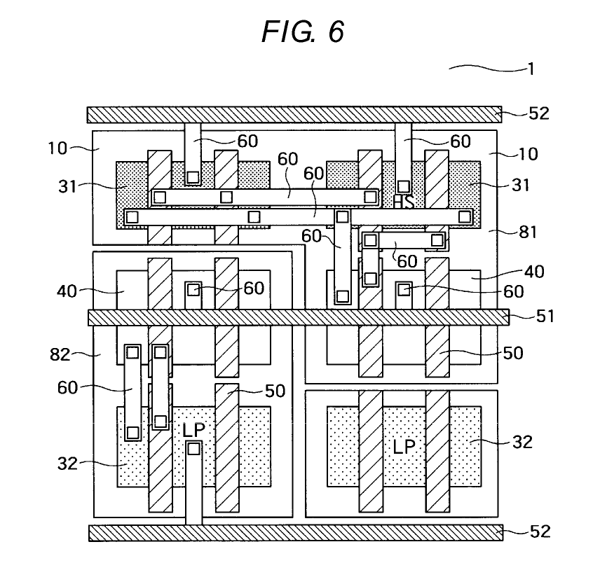

FIG. 6 depicts an integrated circuit configured by forming wiring lines 60 on two basic cells 10 lying next to each other (adjacent) in a direction perpendicular to a line connecting the p-type high-speed transistor pair 31 and the p-type low-power transistor pair 32. The integrated circuit depicted in FIG. 6 has two INV circuit blocks 81 and 82. One INV circuit block (depicted as an upper portion in FIG. 6) 81 includes two p-type high-speed transistor pairs 31, one n-type transistor pair 40, and the wiring lines 60 electrically connecting the p-type high-speed transistor pairs 31 and the n-type transistor pair 40. The INV circuit block 81 is intentionally configured to be imbalanced by making the number of p-type transistor pairs 31 different from the number of n-type transistor pairs 40. The other INV circuit block (depicted as a lower portion in FIG. 6) 82 includes one p-type low-power transistor pair 32, one n-type transistor pair 40, and the wiring lines 60 electrically connecting the p-type low-power transistor pair 31 and the n-type transistor pair 40. As described above, even in the two circuit blocks 81 and 82 in which different types of p-type transistor pairs 31 and 32 are used, since the two circuit blocks 81 and 82 may be disposed in positions lying next to each other, the two circuit blocks 81 and 82 may be connected to each other without the need to route the wiring lines a long distance. Incidentally, the unused transistor (in FIG. 6, the p-type low-power transistor pair 32) may be used as a decoupling capacitor for ensuring the stability of a power supply.

According to this first embodiment, the basic cell 10 includes two types of p-type transistor pairs 31 and 32 and one n-type transistor pair 40. The two p-type transistor pairs 31 and 32 share one n-type transistor pair 40.

Here, as a comparative example, assume that the master slice includes equal numbers of two types of basic cells, a first-type type basic cell including one p-type high-speed transistor pair and one n-type high-speed transistor pair, and a second-type basic cell including one p-type low-power transistor pair and one n-type low-power transistor pair. In this case, for example, when an integrated circuit using only a high-speed transistor is formed, the basic cell (the second-type basic cell) provided with the low-power transistor pair is not used as a circuit element. That is, one basic cell of the two basic cells (one half of the master slice) is not used.

On the other hand, according to the first embodiment, even when an integrated circuit using only a high-speed transistor is formed, only one p-type low-power transistor pair 32 of one basic cell 10 is not used as a circuit element. That is, only one third of the master slice 1 is not used. Incidentally, the same goes for an integrated circuit in which only a low-power transistor is used.

As described above, according to the first embodiment, by making the p-type high-speed transistor pair 31 and the p-type low-power transistor pair 32 share one n-type transistor pair 40, the number of n-type transistor pairs included in the basic cell 10 is reduced. As a result, the number of unused transistor pairs that are not used as circuit elements may be reduced. Therefore, the area of a semiconductor chip for configuring an integrated circuit may be reduced and a production cost of the integrated circuit may be reduced.

In addition, according to the first embodiment, since one basic cell 10 has two types of p-type transistor pairs 31 and 32, even an integrated circuit including both of the two types of p-type transistor pairs 31 and 32 may be configured without drawing out the wiring lines 60 in a long distance. Therefore, resistance of the wiring lines 60 may be reduced and the characteristics of the integrated circuit may be accordingly improved.

Moreover, in the basic cell of the above-described comparative example, a common gate electrode shared by the two transistor pairs is formed in advance in such a way as to electrically connect the p-type transistor pair and the n-type transistor pair. Therefore, in the integrated circuit, the p-type transistor pair and the n-type transistor pair have to be used in combination. On the other hand, in the first embodiment, since the gate electrode 50 is independent for each transistor, the integrated circuit may be configured by combining the transistors arbitrarily via the wiring lines 60.

### Second Embodiment

The second embodiment differs from the first embodiment in that a basic cell 20 has two types of n-type transistor pairs 41 and 42.

### Basic Cell

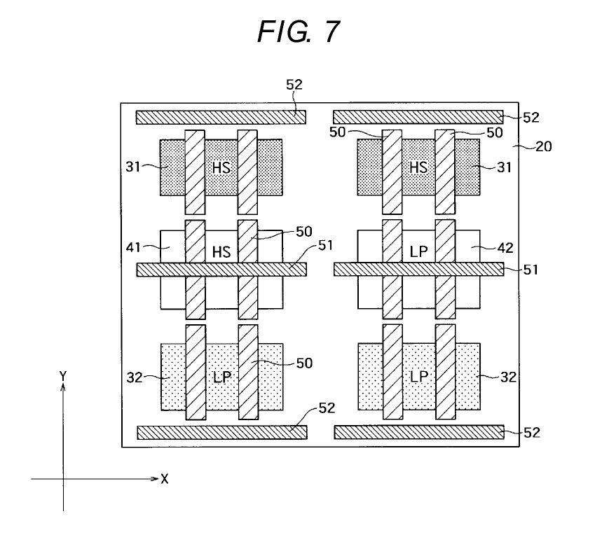

FIG. 7 depicts the basic cell 20 of the second embodiment. The basic cell 20 includes two p-type high-speed transistor pairs 31, two p-type low-power transistor pairs 32, one n-type high-speed transistor pair 41, and one n-type low-power transistor 42. The basic cell 20 includes two columns in the X direction and three rows in the Y direction. In a first row (the top row in FIG. 7), the two p-type high-speed transistor pairs 31 are disposed in such a way as to lie next to each other in the X direction. In a third row (in the bottom row in FIG. 7), the two p-type low-power transistor pairs 32 are disposed in such a way as to lie next to each other in the X direction. Furthermore, in a second row (the center row in FIG. 7) sandwiched between the p-type high-speed transistor pair 31 and the p-type low-power transistor pair 32, the one n-type high-speed transistor pair 41 and the one n-type low-power transistor pair 42 are disposed in such a way as to lie next to each other in the X direction.

According to the second embodiment, since the basic cell 20 includes the two types of n-type transistor pairs 41 and 42, any one of the n-type transistor pairs 41 and 42 may be selected in accordance with the type of the p-type transistor pairs 31 and 32 used in the integrated circuit. In addition, since an integrated circuit may be configured by combining the p-type transistor pair and the n-type transistor pair of the same type, the balance of the integrated circuit is improved.

Furthermore, according to the second embodiment, as in the case of the first embodiment, since the basic cell 20 includes the two types of p-type transistor pairs 31 and 32 and the gate electrode 50 that is independent for each transistor, the same advantages as the advantages of the first embodiment may be produced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An integrated circuit device, comprising:
a plurality of basic cells, each basic cell having:
a first transistor pair including two p-channel transistors of a first-type;
a second transistor pair including two p-channel transistors of a second-type, the second-type transistors configured to consume less power and operate more slowly than the first-type transistors;
a third transistor pair including two n-channel transistors of a third-type, the third transistor pair disposed between the first transistor pair and the second transistor pair; and
a plurality of gate electrodes that are separately provided for each transistor in the first, second, and third transistor pair.

2. The integrated circuit device according to claim 1, wherein the n-channel transistors of the third-type are n-channel high-speed transistors having a threshold voltage value that is closer to a threshold voltage value of the p-channel transistors of the first-type than a threshold voltage value of the p-channel transistors of the second-type.

3. The integrated circuit device according to claim 1, wherein the n-channel transistors of the third-type are n-channel low-power transistors having a threshold voltage value that is closer to a threshold voltage value of the p-channel transistors of the second-type than a threshold voltage value of the p-channel transistors of the first-type.

4. The integrated circuit device according to claim 1, wherein the n-channel transistors of the third-type have a threshold voltage value that is between a threshold voltage value of the p-channel transistors of the first-type and a threshold voltage value of the p-channel transistors of the second-type.

5. The integrated circuit device according to claim 1, wherein the n-channel transistors of the third-type have a threshold voltage value that is equal to one of a threshold voltage value of the p-channel transistors of the first-type and a threshold voltage value of the p-channel transistors of the second-type.

6. The integrated circuit device according to claim 1, further comprising:
a first ground electrode wiring; and
a second ground electrode wiring, wherein the first, second, and third transistor pairs are between the first and second ground electrode wirings when viewed from a direction orthogonal to a plane in which both the first and second ground wirings are located.

7. The integrated circuit device according to claim 6, further comprising:
a power source line disposed between and parallel to the first and second ground electrode wirings when viewed from the direction orthogonal to the plane in which both the first and second ground wirings are located.

8. The integrated circuit device according to claim 1, wherein the plurality of basic cells is disposed in a matrix including rows in which basic cells are in a same orientation such that first transistor pairs are adjacent to each other in a row direction, and columns in which basic cells alternate orientation in a column direction such that rows that are adjacent to each other have one of the first transistor pairs or the second transistor pairs adjacent to each other in the column direction.

9. The integrated circuit device according to claim 1, wherein two basic cells, from the plurality of basic cells, that are adjacent to each other in a first direction that is perpendicular to a line extending between the first transistor pair and the second transistor pair are connected by wirings to form a first circuit block and a second circuit block,
the first circuit block including:
each first transistor pair from the two basic cells, a first third transistor pair from a first basic cell of the two basic cells, and wirings electrically connecting each first transistor pair from the two basic cells and the first third transistor pair, and
the second circuit block including:
a second transistor pair from a second basic cell of the two basic cells, a second third transistor pair from the second basic cell of the two basic cells, and wirings electrically connecting the second transistor pair and the second third transistor pair.

10. The integrated circuit device according to claim 1, wherein the basic cells in the plurality of basic cells each further includes:
a fourth transistor pair adjacent to the first transistor pair in a first direction that is perpendicular to a line extending between the first transistor pair and the second transistor pair, and the fourth transistor pair including two p-channel transistors of the first-type;
a fifth transistor pair adjacent to the second transistor pair in the first direction, and the fifth transistor pair including two p-channel transistors of the second-type; and
a sixth transistor pair adjacent to the third transistor pair in the first direction and disposed between the fourth transistor pair and the fifth transistor pair, the sixth transistor pair including two n-channel transistors of a fourth-type having a threshold voltage value that is different from a threshold voltage value of the n-channel transistors of the third-type.

11. The integrated circuit device according to claim 10, wherein the threshold voltage value of the n-channel transistors of the fourth-type is greater than the threshold voltage value of the n-channel transistors of the third-type.

12. A basic cell for integrated circuits, comprising:
a first transistor pair including two p-channel transistors of a first-type;
a second transistor pair including two p-channel transistors of a second-type, the second-type transistors configured to consume less power and operate more slowly than the first-type transistors;
a third transistor pair including two n-channel transistors of a third-type, the third transistor pair disposed between the first transistor pair and the second transistor pair; and
a plurality of gate electrodes that are separately provided for each transistor in the first, second, and third transistor pair.

13. The basic cell of claim 12, further comprising:
a fourth transistor pair adjacent to the first transistor pair in a first direction that is perpendicular to a line extending between the first transistor pair and the second transistor pair, and the fourth transistor pair including two p-channel transistors of the first-type;
a fifth transistor pair adjacent to the second transistor pair in the first direction, and the fifth transistor pair including two p-channel transistors of the second-type; and
a sixth transistor pair adjacent to the third transistor pair in the first direction and disposed between the fourth transistor pair and the fifth transistor pair, the sixth transistor pair including two n-channel transistors of a fourth-type having a threshold voltage value that is different from a threshold voltage value of the n-channel transistors of the third-type.

14. The basic cell of claim 13, further comprising:
a first ground electrode wiring; and
a second ground electrode wiring, wherein
the first through sixth transistor pairs are between the first and second ground electrode wirings when viewed from a direction orthogonal to a plane in which both the first and second ground wirings are located.

15. The basic cell of claim 13, wherein the plurality of gate electrodes are separately provided for each transistor in the fourth, fifth, and sixth transistor pairs.

16. The basic cell of claim 12, further comprising:
a first ground electrode wiring; and
a second ground electrode wiring, wherein
the first, second, and third transistor pairs are between the first and second ground electrode wirings when viewed from a direction orthogonal to a plane in which both the first and second ground wirings are located.

17. A method of fabricating an integrated circuit device, comprising:
forming a plurality of basic cells on a substrate, each basic cell having:
a first transistor pair including two p-channel transistors of a first-type;
a second transistor pair including two p-channel transistors of a second-type, the second-type transistors configured to consume less power and operate more slowly than the first-type transistors;
a third transistor pair including two n-channel transistors of a third-type, the third transistor pair disposed between the first transistor pair and the second transistor pair;
a plurality of gate electrodes that are separately provided for each transistor in the first, second, and third transistor pair;
a first ground electrode wiring;
a second ground electrode wiring; and
a power source line disposed between and parallel to the first and second ground electrode wirings, wherein the first, second, and third transistor pairs are between the first and second ground electrode wirings when viewed from a direction orthogonal to a plane in which both the first and second ground wirings are located;
forming wiring connections between transistor pairs and between transistor pairs and the first ground electrode wiring, the second ground electrode wiring, or the power source line.

18. The method of claim 17, wherein wiring connections are formed between two basic cells that are adjacent to each other in a first direction that is perpendicular to a line extending between the first transistor pair and the second transistor pair.

19. The method of claim 17, wherein the n-channel transistors of the third-type have a threshold voltage value that is between a threshold voltage value of the p-channel transistors of the first-type and a threshold voltage value of the p-channel transistors of the second-type.

20. The method of claim 17, wherein each basic cell further comprises:
a fourth transistor pair adjacent to the first transistor pair in a first direction that is perpendicular to a line extending between the first transistor pair and the second transistor pair, and the fourth transistor pair including two p-channel transistors of the first-type;
a fifth transistor pair adjacent to the second transistor pair in the first direction, and the fifth transistor pair including two p-channel transistors of the second-type; and
a sixth transistor pair adjacent to the third transistor pair in the first direction and disposed between the fourth transistor pair and the fifth transistor pair, the sixth transistor pair including two n-channel transistors of a fourth-type having a threshold voltage value that is different from a threshold voltage value of the n-channel transistors of the third-type.
